(19) United States
(12) Patent Application Publication
(10) Pub. No.: US 2014/0011350 A1
(43) Pub. Date: Jan. 9, 2014

(54) METHOD OF MANUFACTURING SEMICONDUCTOR DEVICE

(71) Applicant: SAMSUNG ELECTRONICS CO., LTD., Suwon-si (JP)

(72) Inventors: CHOONGKEE SEONG, Seoul (KR); KYUNGHYUN KIM, Seoul (KR); KIJONG PARK, Yongin-si (KR); JIN-I LEE, Yongin-si (KR)

(21) Appl. No.: 13/937,401

(22) Filed: Jul. 9, 2013

(30) Foreign Application Priority Data
Jul. 9, 2012 (KR) 10-2012-0074721

(51) Int. Cl. H01L 29/423

(52) U.S. Cl. CPC H01L 29/42328
USPC 438/593

(57) ABSTRACT

A method of manufacturing a semiconductor device, the method including forming a first gate electrode layer including a semiconductor material on a substrate; performing an annealing process on the first gate electrode layer; performing a dry cleaning process on a surface of the first gate electrode layer after the annealing process; and forming a second gate electrode layer on the first gate electrode layer after the dry cleaning process.

### CROSS-REFERENCE TO RELATED APPLICATION

Korean Patent Application No. 10-2012-0074721 filed on Jul. 9, 2012, in the Korean Intellectual Property Office, and entitled: “METHOD OF MANUFACTURING SEMICONDUCTOR DEVICE,” is incorporated by reference herein in its entirety.

### BACKGROUND

1. Field

Embodiments relate to a method of manufacturing a semiconductor device.

2. Description of the Related Art

A field effect transistor (hereinafter, referred to as ‘a transistor’) is an important element of semiconductor devices. The transistor may include a source and a drain (spaced apart from each other in a semiconductor layer or substrate) and a gate covering a channel region between the source and the drain. Dopants may be injected into the semiconductor substrate to form the source and the drain, and the gate may be insulated from the channel region by a gate insulating layer between the semiconductor substrate and the gate. The transistors may be used as switching elements and/or elements constituting a logic circuit.

### SUMMARY

Embodiments are directed to a method of manufacturing a semiconductor device.

The embodiments may be realized by providing a method of manufacturing a semiconductor device, the method including forming a first gate electrode layer including a semiconductor material on a substrate; performing an annealing process on the first gate electrode layer; performing a dry cleaning process on a surface of the first gate electrode layer after the annealing process; and forming a second gate electrode layer on the first gate electrode layer after the dry cleaning process.

Impurities in the first gate electrode layer may be segregated at a surface of the first gate electrode layer to form an impurity layer, and the impurity layer may be removed by the dry cleaning process.

The impurities may include oxygen or boron.

The dry cleaning process may be performed using a cleaning gas including a NF₃ gas.

The cleaning gas may further include a NH₃ gas, and a volume ratio of the NF₃ gas to the NH₃ gas may be about 8:1 to about 12:1.

The dry cleaning process may be performed under a pressure of about 2 Torr to about 5 Torr.

The dry cleaning process may be performed at a temperature of about 30 degrees Celsius or less.

Performing the dry cleaning process may include performing a remote plasma process.

The method may further include performing a wet cleaning process on the first gate electrode layer after the annealing process and before the dry cleaning process.

The method may further include performing a wet cleaning process on the first gate electrode layer after the dry cleaning process and before formation of the second gate electrode layer.

Silicon oxide formed by natural oxidation of the first gate electrode layer may be removed by the wet cleaning process.

The first gate electrode layer may include a first semiconductor layer and a second semiconductor layer; and a dopant-concentration of the second semiconductor layer may be different from a dopant-concentration of the first semiconductor layer.

The dopant-concentration of the second semiconductor layer may be greater than the dopant-concentration of the first semiconductor layer.

The dopant may be boron.

The method may further include forming a diffusion preventing layer between the first gate electrode layer and the second gate electrode layer; forming a floating gate electrode between the substrate and the first gate electrode layer; and forming a blocking insulating layer between the floating gate electrode and the first gate electrode layer.

The embodiments may also be realized by providing a method of manufacturing a semiconductor device, the method including providing a substrate; forming a first gate electrode layer on the substrate such that the first gate electrode layer includes a semiconductor material; concentrating impurities at a surface of the first gate electrode layer to create a concentrated impurity region in a form of an impurity layer; removing the concentrated impurity region at the surface of the first gate electrode layer; and forming a second gate electrode layer on the first gate electrode layer after removing the concentrated impurity region.

Concentrating the impurities at the surface of the first gate electrode layer may include performing an annealing process on the first gate electrode layer.

Removing the concentrated impurity region at the surface of the first gate electrode layer may include performing a dry cleaning process on the surface of the first gate electrode layer.

Performing the dry cleaning process may include using a cleaning gas including a NF₃ gas.

The method may further include removing a silicon oxide layer from the first gate electrode layer prior to forming the second gate electrode layer.

### BRIEF DESCRIPTION OF THE DRAWINGS

Features will become apparent to those of skill in the art by describing in detail exemplary embodiments with reference to the attached drawings in which:

FIG. 1 illustrates a plan view of a semiconductor device according to an embodiment;

FIG. 2 illustrates a flowchart of a method of manufacturing a semiconductor device according to an embodiment;

FIG. 3 illustrates a schematic diagram of a remote plasma apparatus according to an embodiment;

FIGS. 4A to 14A illustrate cross-sectional views taken along a line I-I′ of FIG. 1 to show stages in a method of manufacturing a semiconductor device according to an embodiment;

FIGS. 4B to 14B illustrate cross-sectional views taken along a line II-II′ of FIG. 1 to show stages in a method of manufacturing a semiconductor device according to an embodiment;

FIG. 15 illustrates a flowchart of a method of manufacturing a semiconductor device according to an embodiment;

FIG. 16 illustrates a schematic block diagram of an example of electronic devices including semiconductor devices according to an embodiment; and

FIG. 17 illustrates a schematic block diagram of an example of memory cards including semiconductor devices according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

The advantages and features of the embodiments and methods of achieving them will be apparent from the following exemplary embodiments that will be described in more detail with reference to the accompanying drawings. In the drawings, embodiments are not limited to the specific examples provided herein and are exaggerated for clarity.

The terminology used herein is for the purpose of describing particular embodiments only and is not intended to limit. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views. Accordingly, shapes of the exemplary views may be modified according to manufacturing techniques and/or allowable errors. Therefore, the embodiments are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the embodiments.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the embodiments. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

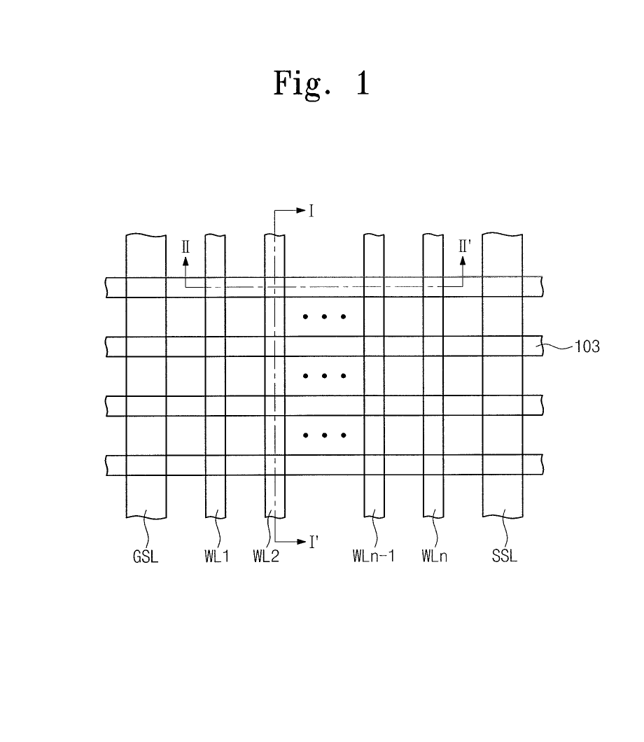

FIG. 1 illustrates a plan view of a semiconductor device according to an embodiment.

Referring to FIG. 1, a semiconductor device according to an embodiment may include active regions 103 defined at a substrate. The active regions 103 may be in parallel to each other. A string selection line SSL and a ground selection line GSL may cross over the active regions 103. A plurality of word lines WL1, WL2, WLn−1, and WLn may be disposed between the string selection SSL and the ground selection line GSL and may cross over the active regions 103. In an implementation, the string selection line SSL, the ground selection line GSL, and the word lines WL1, WL2, WLn−1, and WLn may be parallel to each other.

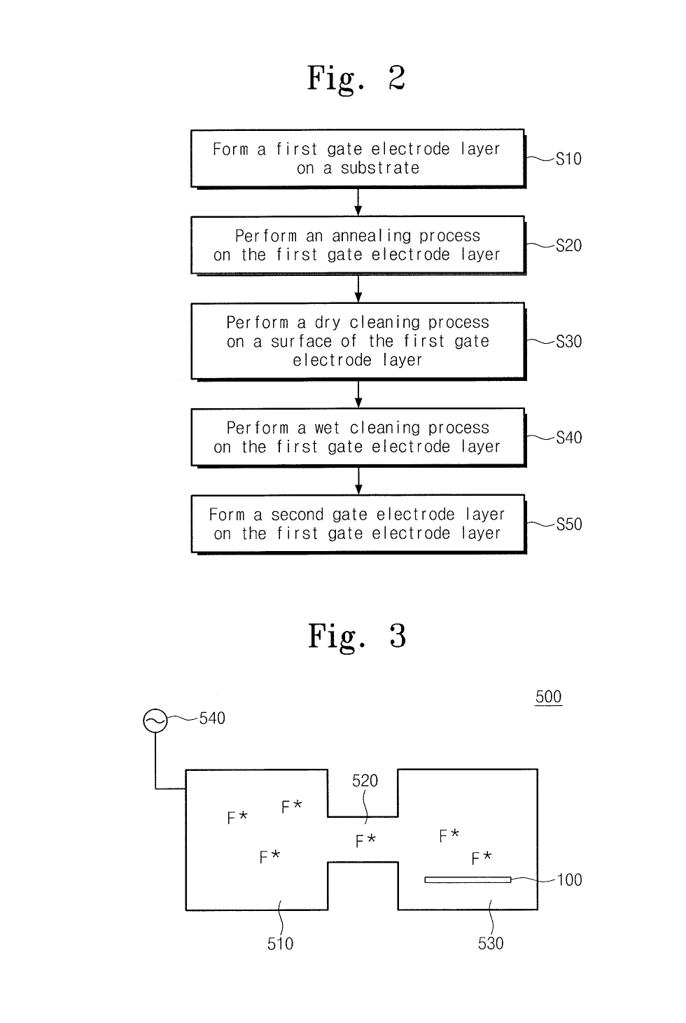

Hereinafter, a method of manufacturing a semiconductor device according to an embodiment will be described with reference to FIGS. 2, 3, 4A to 14A, and 4B to 14B.

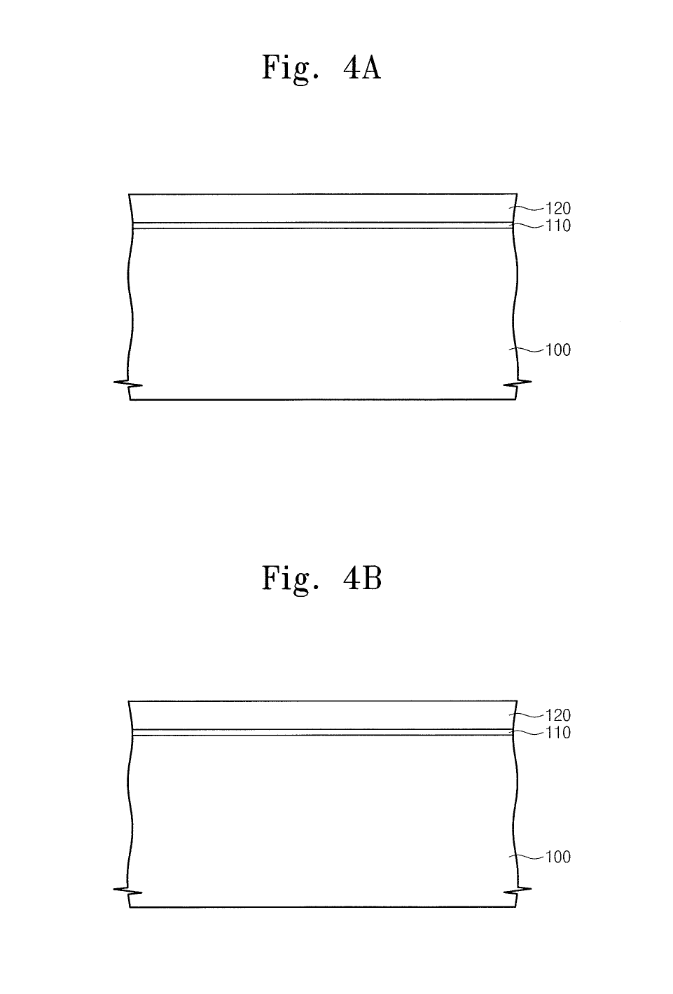

FIG. 2 illustrates a flowchart of a method of manufacturing a semiconductor device according to an embodiment. FIG. 3 illustrates a schematic diagram of a remote plasma apparatus according to an embodiment. FIGS. 4A to 14A illustrate cross-sectional views taken along a line I-I′ of FIG. 1 to show stages in a method of manufacturing a semiconductor device according to an embodiment. FIGS. 4B to 14B illustrate cross-sectional views taken along a line II-II′ of FIG. 1 to show stages in a method of manufacturing a semiconductor device according to an embodiment.

Referring to FIGS. 4A and 4B, a substrate 100 may be provided. The substrate 100 may include a silicon substrate. In an implementation, the substrate 100 may include a single-crystalline silicon layer, silicon on insulator (SOI), or a silicon-germanium (SiGe) layer. A mask layer 120 may be provided on the substrate 100. The mask layer 120 may include a silicon nitride layer. The silicon nitride layer of the mask layer 120 may be formed by a chemical vapor deposition (CVD) process. A pad layer 110 may be provided between the mask layer 120 and the substrate 100. The pad layer 110 may include a silicon oxide layer. The pad layer 110 may be formed by a thermal oxidation process or a CVD process.

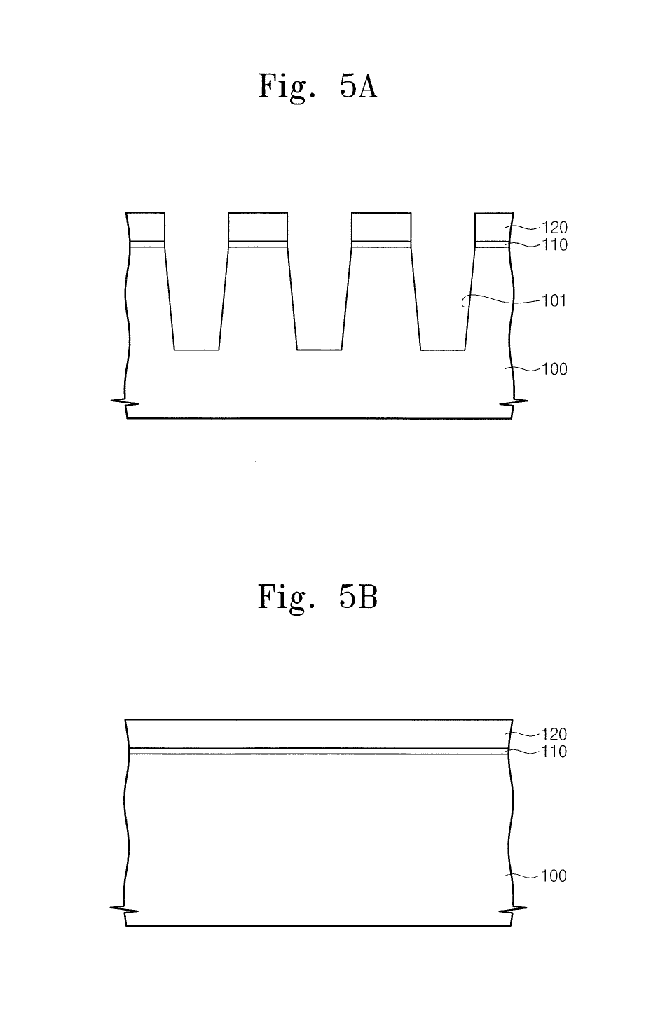

Referring to FIGS. 5A and 5B, the mask layer 120 and the pad layer 110 may be etched using a photoresist pattern (not illustrated) to expose portions of the substrate 100. Thereafter, the exposed portions of the substrate 100 may be etched using the etched mask layer 120 and the etched pad layer 110 as etch masks, thereby forming trenches 101.

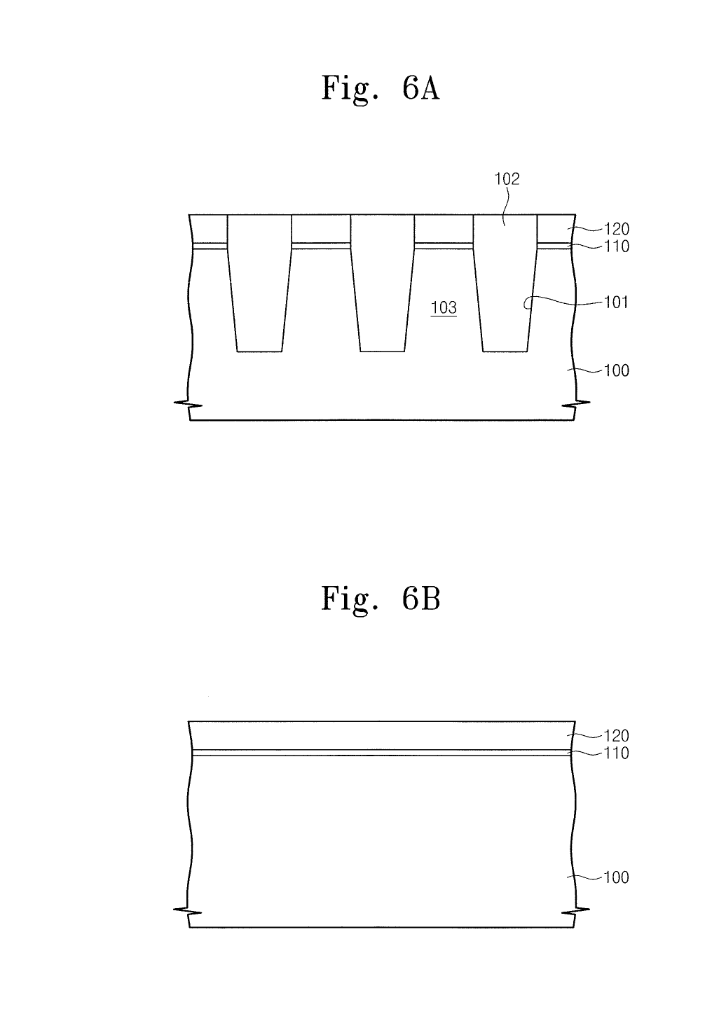

Referring to FIGS. 6A and 6B, device isolation layers 102 may be formed to fill the trenches 101, respectively. The device isolation layers 102 may include silicon oxide. A liner nitride layer (not illustrated) may be formed between an inner surface of the trench 101 and the device isolation layer 102. Before the liner nitride layer is formed, a thermal oxide layer (not illustrated) may be formed on the inner surface of the trench 101. The device isolation layers 102 may define the active regions 103.

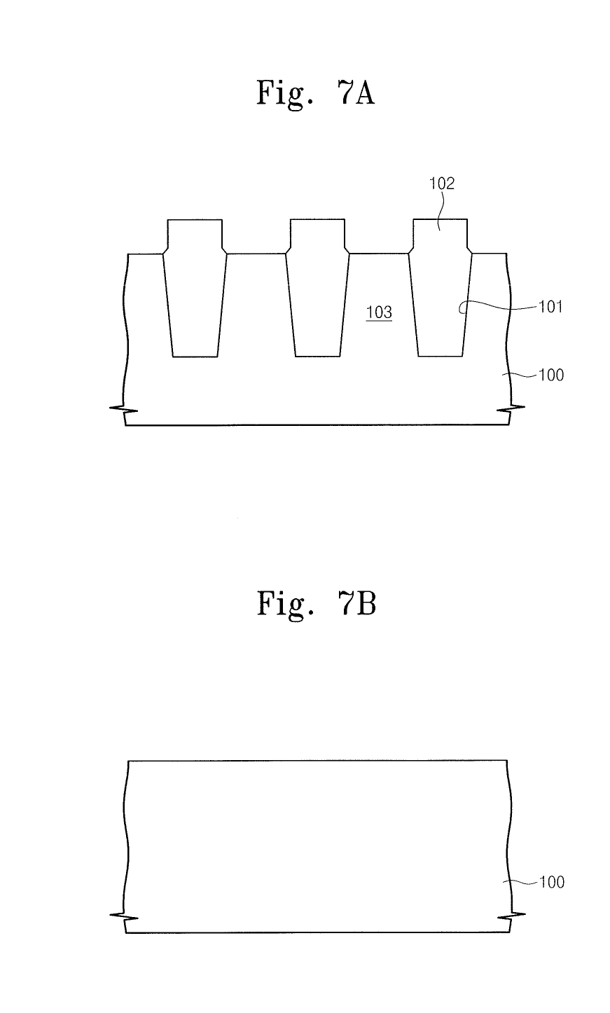

Referring to FIGS. 7A and 7B, the mask layer 120 and the pad layer 110 may be removed to expose the active regions 103. The mask layer 120 and the pad layer 110 may be removed by a wet etching process. A sidewall of the device isolation layer 102 may be partially etched during the removal of the mask layer 120 and the pad layer 110.

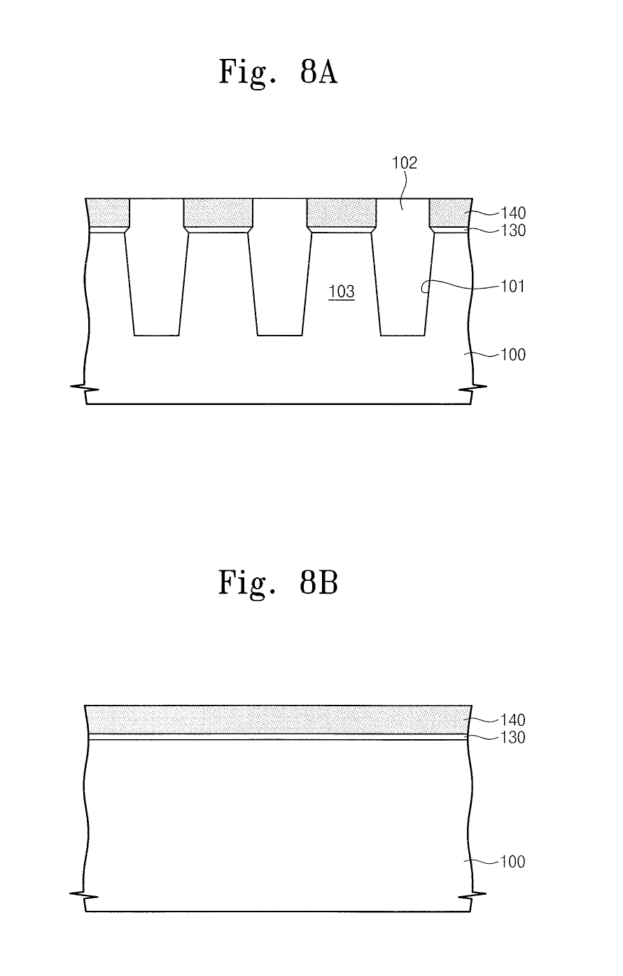

Referring to FIGS. 8A and 8B, a tunneling insulating layer 130 may be formed on the exposed active region 103. The tunneling insulating layer 130 may be formed by, e.g., a thermal oxidation process. The tunneling insulating layer 130 may include a silicon oxide layer and/or a high-k dielectric layer having a dielectric constant greater than that of the silicon oxide layer. For example, the high-k dielectric layer may include a hafnium oxide layer and/or a zirconium oxide layer. The tunneling insulating layer 130 may have a thickness of about 10 Å to about 100 Å

A floating gate electrode 140 may be formed on the tunneling insulating layer 130. The floating gate electrode 140 may be formed using a deposition process and a planarizing process. Due to the planarizing process, a plurality of the floating gate electrodes 140 may be separated from each other by the device isolation layers 102. The floating gate electrodes 140 may include doped poly-silicon, a metal, a metal silicide, or a combination thereof.

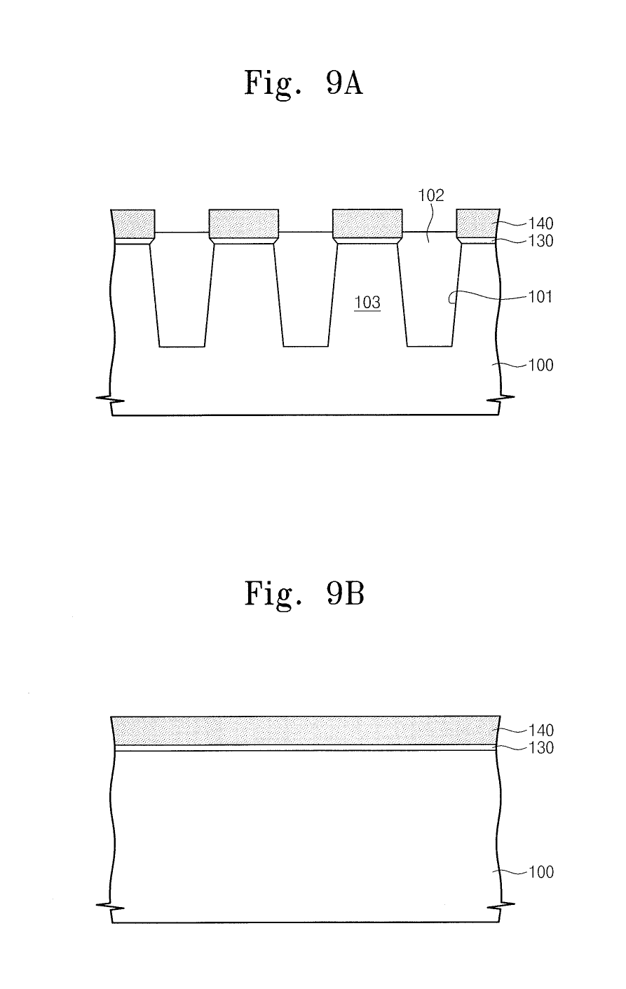

Referring to FIGS. 9A and 9B, the device isolation layers 102 may be recessed.

A recessing process may include an anisotropic etching process. Portions of the device isolation layers 102 may be removed such that the device isolation layers 102 may be recessed. Thus, sidewalls of the floating gate electrodes 140 may be exposed. Top surfaces of the recessed device isolation layers 102 may be higher than top surfaces of the active regions 103.

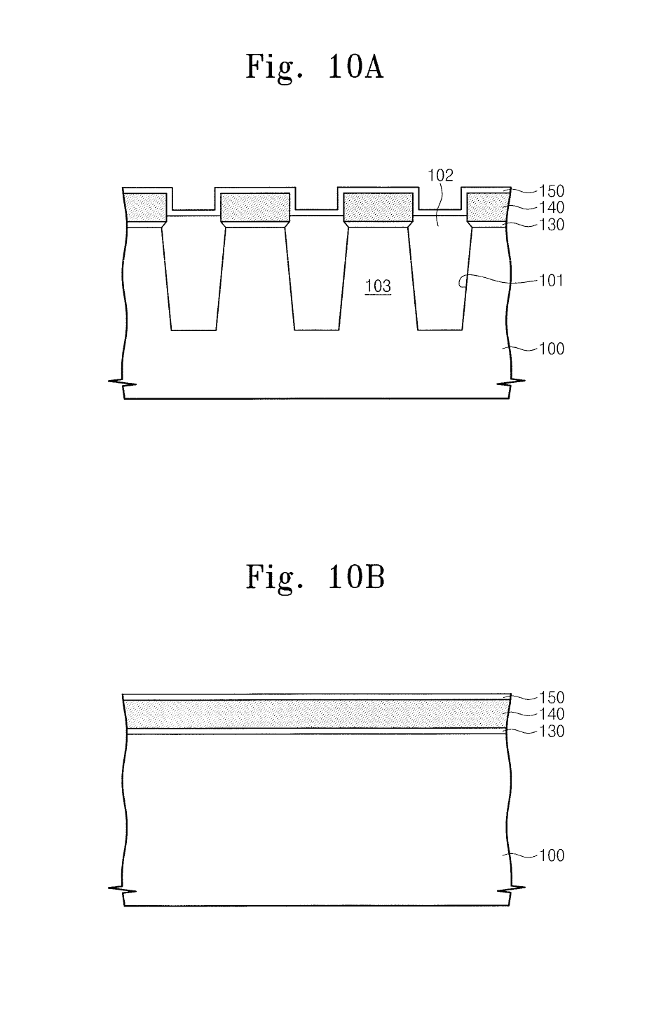

Referring to FIGS. 10A and 10B, a blocking insulating layer 150 may be formed on the recessed device isolation layers 102 and the floating gate electrodes 140. The blocking insulating layer 150 may be formed by, e.g., an atomic layer deposition (ALD) process or a CVD process. The blocking insulating layer 150 may include a silicon oxide layer and/or a silicon nitride layer. In an implementation, the blocking insulating layer 150 may include an oxide-nitride-oxide (ONO) layer.

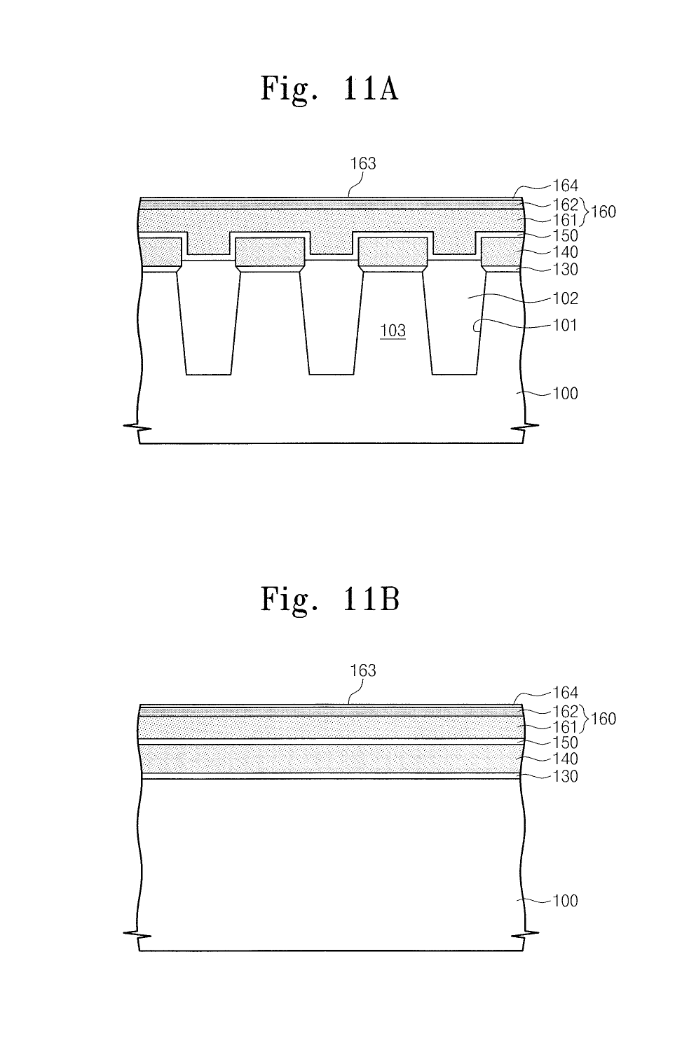

Referring to FIGS. 2, 11A, and 11B, a first gate electrode layer 160 may be formed on the blocking insulating layer 150 (S10). The first gate electrode layer 160 may include a semiconductor material. For example, the first gate electrode layer 160 may include a first semiconductor layer 161 on the blocking insulating layer 150 and a second semiconductor layer 162 on the first semiconductor layer 161, such that the first semiconductor layer 161 is between the blocking insulating layer 150 and the second semiconductor layer 162. In an implementation, each of the first and second semiconductor layers 161 and 162 may include poly-silicon doped with dopants. For example, the dopant may be or may include boron (B). A dopant-concentration of the first semiconductor layer 161 may be different from a dopant-concentration of the second semiconductor layer 162. In an implementation, the dopant-concentration of the second semiconductor layer 162 may be greater than the dopant-concentration of the first semiconductor layer 161.

An annealing process may be performed on the first gate electrode layer 160 (S20). An electron-mobility of the first gate electrode layer 160 may be increased as a result of the annealing process. The annealing process may be performed at a temperature of about 600 degrees Celsius or more. Impurities included in the first gate electrode layer 160 may be diffused to and then segregated at a surface 163 of the first gate electrode layer 160 as a result of the annealing process. The segregated impurities may be formed into an impurity layer 164. The impurities may include oxygen (O) and/or boron (B). In an implementation, the dopants (e.g., boron) doped in the first gate electrode layer 160 may be more highly concentrated in the impurity region 164 than in other portions, e.g., a lower portion, of the second semiconductor layer 162. For example, a boron concentration of the impurity layer 164 may be several times to tens of times greater than that of the lower portion of the second semiconductor layer 162. The impurity layer 164 may include silicon oxide formed by natural oxidation. The impurity layer 164 may function as a resistance factor of a metal gate that will be formed in a subsequent process. Thus, removing the impurity layer 164 may be desirable.

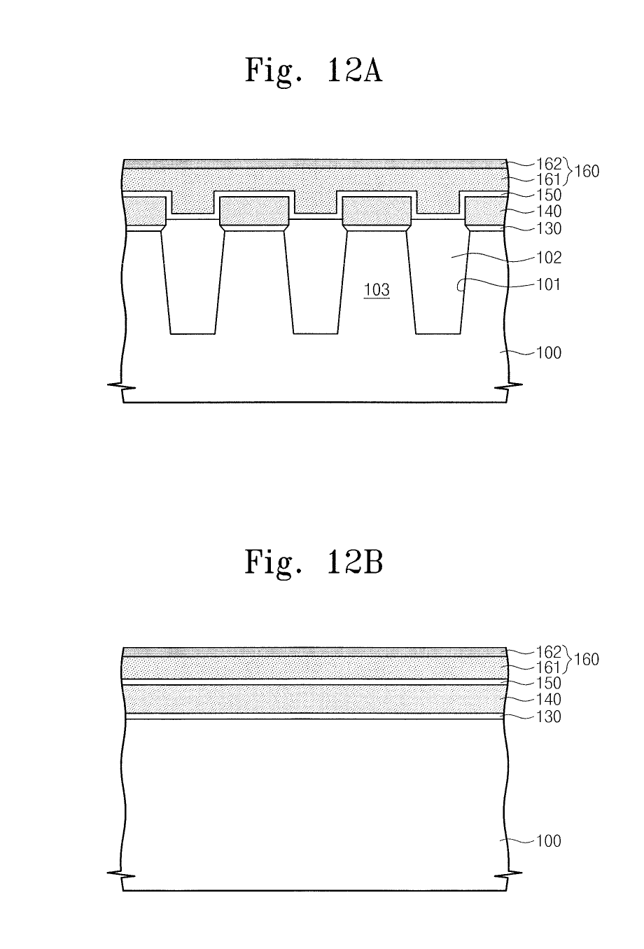

Referring to FIGS. 2, 12A, and 12B, after the annealing process, a dry cleaning process may be performed on the surface 163 of the first gate electrode layer 160 (S30). The dry cleaning process may be performed using a cleaning gas including NF₃ gas. In an implementation, the cleaning gas may include the NF₃ gas as well as NH₃ gas. An amount of the NF₃ gas may be greater than an amount of the NH₃ gas in the dry cleaning process. For example, a volume ratio of the NF₃ gas to the NH₃ gas may be about 8:1 to about 12:1. In an implementation, a flow rate of the NF₃ gas may be equal to or greater than about 100 sccm, and a flow rate of the NH₃ gas may be equal to or greater than about 10 sccm. The dry cleaning process may be performed at a temperature of about 30 degrees Celsius or less. The dry cleaning process may be performed under a pressure of about 2 Torr to about 5 Torr. The dry cleaning process may be performed for a process time of about 10 seconds to about 60 seconds

In an implementation, the dry cleaning process may be performed using a remote plasma method. In the remote plasma method, a plasma generating part may be spaced apart from a processing part. Referring to FIG. 3, a remote plasma apparatus 500 may include a plasma generating part 510, a processing part 530, and a plasma transfer part 520 connecting the plasma generating part 510 to the processing part 530. In the plasma generating part 510, an energy source 540 may apply energy (e.g., a microwave energy) to the cleaning gas supplied from an external system, so as to generate plasma. The plasma may be transferred into the processing part 530 through the plasma transfer part 520. The substrate 100 in processing part 530 may be treated by the plasma. In an implementation, the plasma generating part 510 may apply the energy to the cleaning gas including the NF₃ gas, so as to generate fluorine radicals F*. The fluorine radicals F* may be transferred into the processing part 530 through the plasma transfer part 520. The plasma radicals F* may react with the impurity layer 164 on the substrate 100 in the process part 530, so that the impurity layer 164 may be removed.

The remote plasma method may increase a ratio of conversion from the cleaning gas to the plasma, compared with a method of directly generating plasma in the processing part. Thus, the remote plasma method may have a reactivity greater than that of the method of directly generating the plasma in the processing part. Thus, the dry cleaning process may be performed by the remote plasma method, such that the impurity layer 164 may be effectively removed.

A removal mechanism of the impurity layer 164 by the dry cleaning process will be described hereinafter. The fluorine radicals F* may react with the impurity layer 164. For example, the fluorine radicals F* may be substituted for oxygen atoms of silicon-oxygen (Si—O) bonds and/or boron atoms of silicon-boron (Si—B) bonds, such that silicon-fluorine (Si—F) bonds may be formed. Due to the substitution, silicon tetrafluoride (SiF₄) having strong volatility may be formed, and the separated oxygen atoms and separated boron atoms may be removed. As a result, the impurity layer 164 may be etched.

Referring to FIG. 2, after the dry cleaning process, a wet cleaning process may be performed on the first gate electrode layer 160 (S40). The wet cleaning process may be performed using a cleaning agent including hydrogen fluoride (HF). Silicon oxide formed by the natural oxidation of the first gate electrode layer 160 may be additionally removed by the wet cleaning process.

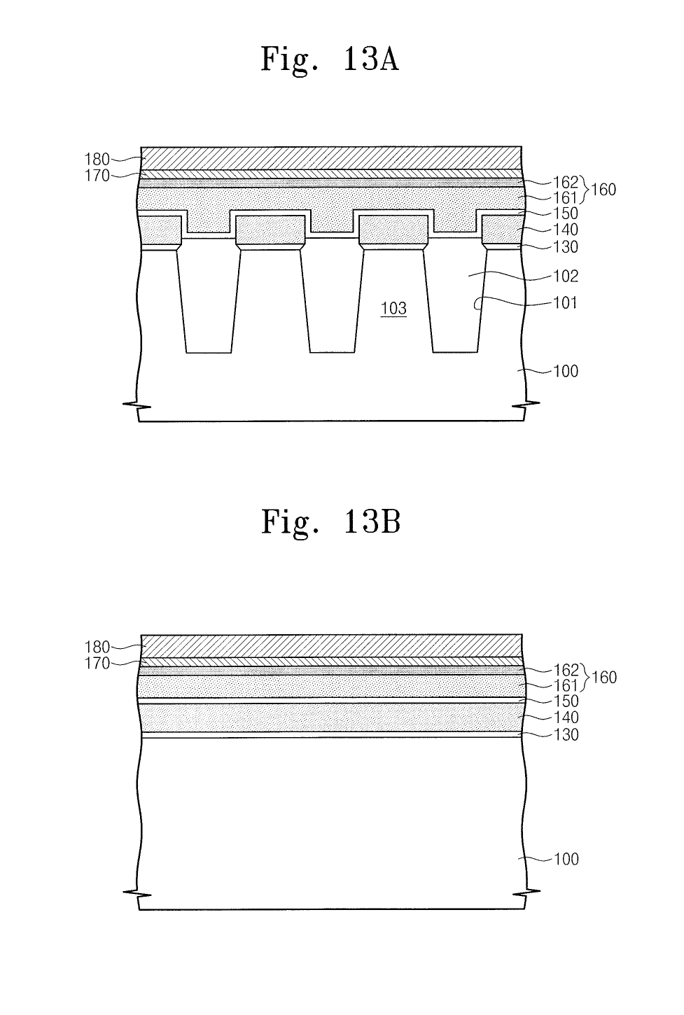

Referring to FIGS. 2, 13A, and 13B, after the wet cleaning process, a second gate electrode layer 180 may be formed on the first gate electrode layer 160 (S50). The second gate electrode layer 180 may include a metal. For example, the second gate electrode layer 180 may include at least one of tungsten (W), molybdenum (Mo), tantalum (Ta), titanium (Ti), ruthenium (Ru), iridium (Ir), or platinum (Pt).

A diffusion preventing layer 170 may be formed between the first gate electrode layer 160 and the second gate electrode layer 180. The diffusion preventing layer 170 may prevent diffusion and reaction between the first and second gate electrode layers 160 and 180. The diffusion preventing layer 170 may include a metal and/or a conductive metal nitride. For example, the diffusion preventing layer 170 may include at least one of titanium (Ti), cobalt (Co), molybdenum (Mo), platinum (Pt), iridium (Ir), ruthenium (Ru), chromium (Cr), tantalum (Ta), zirconium (Zr), or conductive metal nitrides thereof.

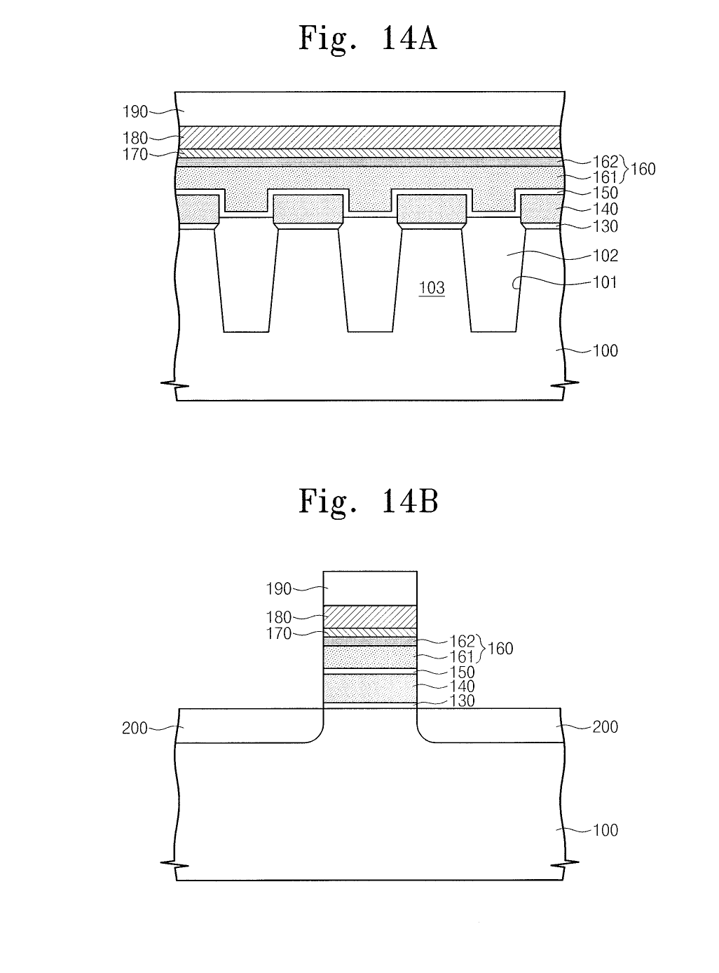

Referring to FIGS. 14A and 14B, a capping layer 190 may be formed on the second gate electrode layer 180. The capping layer 190 may protect a structure under the capping layer 190 in a subsequent process and may function as an etch mask during a gate etching process. The capping layer 190 may include, e.g., an oxide layer, a nitride layer, an oxynitride layer, or a combination thereof. The second gate electrode layer 180, the diffusion preventing layer 170, the first gate electrode layer 160, the blocking insulating layer 150, and/or the floating gate electrode 140 may be patterned using the capping layer 190 as an etch mask. The patterned second gate electrode layer 180, diffusion preventing layer 170, and first gate electrode layer 160 may be used as a control gate electrode in the semiconductor device. The patterned floating gate electrode 140 may be used as a floating gate in the semiconductor device. N-type or P-type dopants may be injected into the active region 103 (i.e., the substrate 100) at sides of the control gate electrode to form source/drain regions 200.

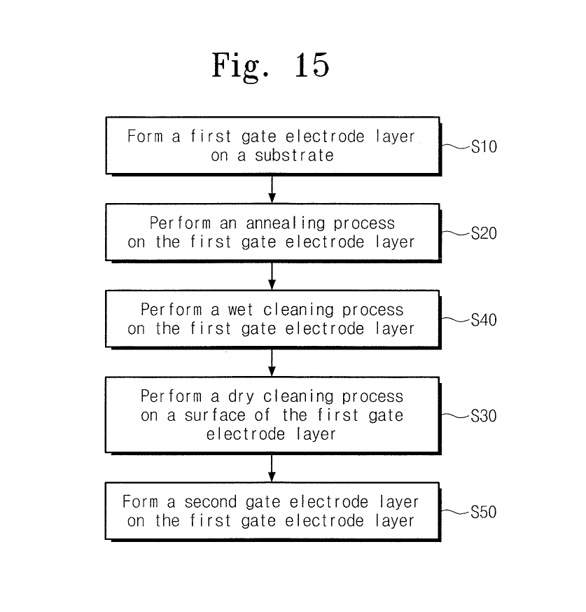

A method of manufacturing a semiconductor device according to another embodiment will be described with reference to FIG. 15. For the purpose of ease and convenience, repeated descriptions to the same compositions as in the above embodiment may be omitted or described briefly.

Referring to FIG. 15, the wet cleaning process may be performed prior to the dry cleaning process. For example, the wet cleaning process (S40) may be performed on the first gate electrode layer 160 after the annealing process (S20) and prior to the dry cleaning process (S30). The wet cleaning process may be performed using the cleaning agent including hydrogen fluoride (HF). Silicon oxide of the first gate electrode layer 160 formed by the natural oxidation may be removed by the wet cleaning process. After the wet cleaning process, the dry cleaning process may be performed on the surface 163 of the first gate electrode layer 160 (S30). After the dry cleaning process, the second gate electrode layer 180 may be formed on the first gate electrode layer 160 (S50).

As described above, the impurity layer 164 (functioning as a resistance factor) may be effectively removed by the dry cleaning process. Thus, an interface resistivity between the gate electrode layers may be reduced in the semiconductor device according to an embodiment.

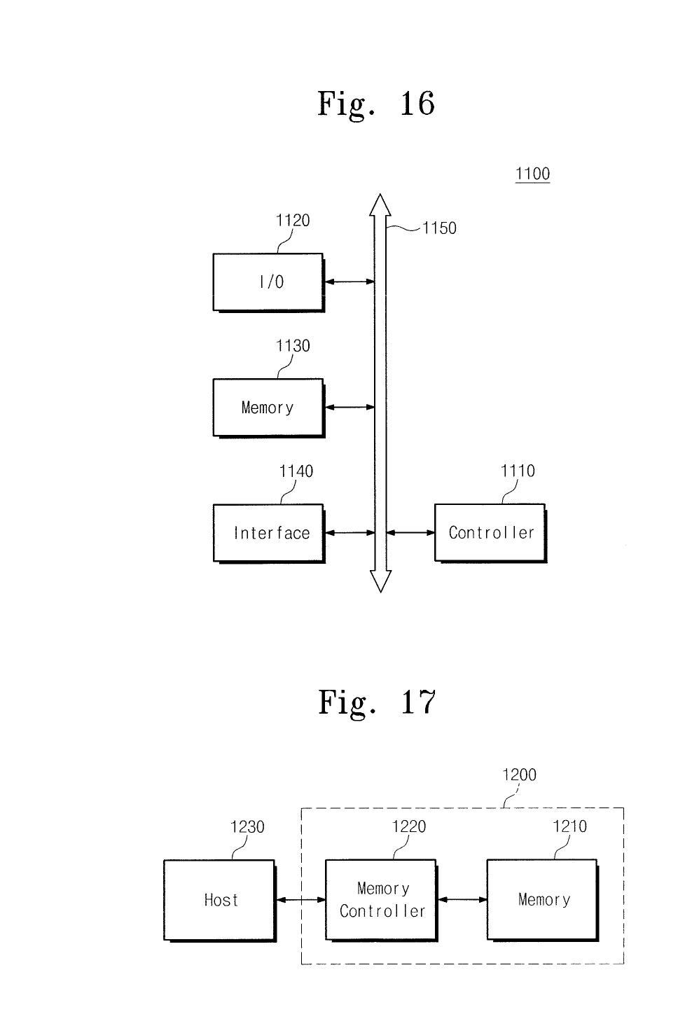

FIG. 16 illustrates a schematic block diagram of an example of electronic devices including semiconductor devices according to an embodiment.

Referring to FIG. 16, an electronic system 1100 according to an embodiment may include a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150. The data bus 1150 may correspond to a path through which electrical signals are transmitted.

The controller 1110 may include at least one of a microprocessor, a digital signal processor, a microcontroller, or other logic devices having a similar function to any one of the microprocessor, the digital signal processor, and the microcontroller. The I/O unit 1120 may include a keypad, a keyboard, and/or a display unit. The memory device 1130 may store data and/or commands. The memory device 1130 may include at least one of semiconductor devices manufactured according to embodiments of the inventive concept. The memory device 1130 may further include another type of semiconductor memory devices that are different from the semiconductor devices described above. The interface unit 1140 may operate by wireless or cable. For example, the interface unit 1140 may include an antenna for wireless communication or a transceiver for cable communication.

The electronic system 1100 may be applied to, e.g., a personal digital assistant (PDA), a portable computer, a web tablet, a wireless phone, a mobile phone, a digital music player, a memory card, or other electronic products. The other electronic products may receive or transmit information data by wireless.

FIG. 17 illustrates a schematic block diagram of an example of memory cards including semiconductor device according to an embodiment.

Referring to FIG. 17, a memory card 1200 according to an embodiment may include a memory device 1210. The memory device 1210 may include at least one of semiconductor devices manufactured according to an embodiment. The memory device 1210 may further include another type of semiconductor memory devices that are different from the semiconductor devices manufactured according to the embodiments described above. The memory card 1200 may further include a memory controller 1220 that controls data communication between a host 1230 and the memory device 1210.

According to the embodiments, an interface between the first gate electrode layer and the second gate electrode layer may be dry-cleaned to help improve a resistance characteristic of the semiconductor device.

By way of summation and review, while high speed semiconductor devices have been increasingly demanded, the semiconductor devices have been highly integrated. Thus, sizes of the transistors may be reduced, such that the operation speeds of the semiconductor devices may be reduced by various causes. Reducing a resistance of the gate for improving the operation speed of the semiconductor device may be desirable. Embodiments provide methods of manufacturing a semiconductor device having a gate with an improved resistance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a semiconductor device, the method comprising:
forming a first gate electrode layer including a semiconductor material on a substrate;
performing an annealing process on the first gate electrode layer;
performing a dry cleaning process on a surface of the first gate electrode layer after the annealing process; and
forming a second gate electrode layer on the first gate electrode layer after the dry cleaning process.

2. The method as claimed in claim 1, wherein:
impurities in the first gate electrode layer are segregated at a surface of the first gate electrode layer to form an impurity layer, and
the impurity layer is removed by the dry cleaning process.

3. The method as claimed in claim 2, wherein the impurities include oxygen or boron.

4. The method as claimed in claim 1, wherein the dry cleaning process is performed using a cleaning gas including a NF₃ gas.

5. The method as claimed in claim 4, wherein:
the cleaning gas further includes a NH₃ gas, and
a volume ratio of the NF₃ gas to the NH₃ gas is about 8:1 to about 12:1.

6. The method as claimed in claim 5, wherein the dry cleaning process is performed under a pressure of about 2 Torr to about 5 Torr.

7. The method as claimed in claim 5, wherein the dry cleaning process is performed at a temperature of about 30 degrees Celsius or less.

8. The method as claimed in claim 5, wherein performing the dry cleaning process includes performing a remote plasma process.

9. The method as claimed in claim 1, further comprising performing a wet cleaning process on the first gate electrode layer after the annealing process and before the dry cleaning process.

10. The method as claimed in claim 1, further comprising performing a wet cleaning process on the first gate electrode layer after the dry cleaning process and before formation of the second gate electrode layer.

11. The method as claimed in claim 10, wherein silicon oxide formed by natural oxidation of the first gate electrode layer is removed by the wet cleaning process.

12. The method as claimed in claim 1, wherein:
the first gate electrode layer includes a first semiconductor layer and a second semiconductor layer; and
a dopant-concentration of the second semiconductor layer is different from a dopant-concentration of the first semiconductor layer.

13. The method as claimed in claim 12, wherein the dopant-concentration of the second semiconductor layer is greater than the dopant-concentration of the first semiconductor layer.

14. The method as claimed in claim 12, wherein the dopant is boron.

15. The method as claimed in claim 1, further comprising:
forming a diffusion preventing layer between the first gate electrode layer and the second gate electrode layer;
forming a floating gate electrode between the substrate and the first gate electrode layer; and
forming a blocking insulating layer between the floating gate electrode and the first gate electrode layer.

16. A method of manufacturing a semiconductor device, the method comprising:
providing a substrate;
forming a first gate electrode layer on the substrate such that the first gate electrode layer includes a semiconductor material;
concentrating impurities at a surface of the first gate electrode layer to create a concentrated impurity region in a of an impurity layer;
removing the concentrated impurity region at the surface of the first gate electrode layer; and
forming a second gate electrode layer on the first gate electrode layer after removing the concentrated impurity region.

17. The method as claimed in claim 16, wherein concentrating the impurities at the surface of the first gate electrode layer includes performing an annealing process on the first gate electrode layer.

18. The method as claimed in claim 16, wherein removing the concentrated impurity region at the surface of the first gate electrode layer includes performing a dry cleaning process on the surface of the first gate electrode layer.

19. The method as claimed in claim 18, wherein performing the dry cleaning process includes using a cleaning gas including a NF₃ gas.

20. The method as claimed in claim 16, further comprising removing a silicon oxide layer from the first gate electrode layer prior to forming the second gate electrode layer.
